(19) United States
(12) Patent Application Publication
(10) Pub. No.: US 2004/0106256 A1
(43) Pub. Date: Jun. 3, 2004

(54) Method of manufacturing a flash memory cell

(75) Inventors: Cha Deok Dong, Ichon-Shi (KR); Noh Yeal Kwak, Ichon-Shi (KR)

Correspondence Address: JACOBSON HOLMAN PLLC, 400 SEVENTH STREET N.W., SUITE 600, WASHINGTON, DC, 20004, US

(73) Assignee: Hynix Semiconductor Inc.

(21) Appl. No.: 10/706,932

(22) Filed: Nov. 14, 2003

Related U.S. Application Data
(62) Division of application No. 10/287,785, filed on Nov. 5, 2002, now abandoned.

(30) Foreign Application Priority Data
Dec. 22, 2001 (KR) 2001-83496

(51) Int. Cl. H01L 21/336; H01L 21/76

(52) U.S. Cl. 438/257; 438/424

(57) ABSTRACT

The present invention relates to a method of manufacturing a flash memory cell. A tunnel oxide film is formed before a trench is formed and an exposed portion is then etched by a given thickness. Therefore, a phenomenon that the corner of the trench is thinly formed by a sidewall oxidization process is prevented and an active region of a desired critical dimension can be secured.

### BACKGROUND OF THE INVENTION

1. Field of the Invention

The invention relates generally to a method of manufacturing a flash memory cell, and more particularly to, a method of forming a self-aligned floating gate in a flash memory cell.

2. Description of the Prior Art

A flash memory cell is implemented by means of a device isolation process using a shallow trench isolation (STI) process. Upon the isolation process of the floating gate using mask patterning, wafer uniformity is very bad due to variation in the critical dimension (CD). It is thus difficult to implement a uniform floating gate. Also, there occur problems such as program and erase fail of the memory cell occurring due to variation in the coupling ratio, and the like.

In addition, in view of high-integrated design, when a space of below 0.15 μm is tried to be implemented, the mask process is made further difficult. Due to this, a process of manufacturing the flash memory cell serving as an important factor in implementing the uniform floating gate is made further difficult. Further, if the floating gate is not uniformly formed, there is an over-erase problem upon program and ease of the memory cell, etc. due to severe difference in the coupling ratio. This adversely, affects a device characteristic and also causes to lower the yield of a product and increase the manufacturing cost due to an increase in the mask process.

Due to the above problems, in a flash memory cell of 0.13 μm technology, the floating gate is formed by a self-aligned mode without performing the mask process and etch process for the floating gate.

In the STI process of a conventional self-aligned mode, however, a tunnel oxide film for a gate oxide film is formed on a semiconductor substrate by means of a sidewall oxidization process using a wall sacrificial (SAC) oxidization process and wall oxidization process. In this case, there are problems that the tunnel oxide film is not uniformly formed on the semiconductor substrate, and gate thinning the thickness of which is smaller than a deposition target occurs at the corner of the trench.

Meanwhile, upon the STI process of the conventional technology, an advanced lithography process is required in order to sufficiently reduce the critical dimension (CD) of an active region that is defined by the trench. For this, expensive equipment is required which may cause to increase the manufacturing cost. In addition, upon the STI process, there is a limitation in increasing the capacitance applied to a dielectric film since the surface area of the floating gate is not effectively increased. Due to this, it is very difficult to increase the coupling ratio.

### SUMMARY OF THE INVENTION

The present invention is contrived to solve the above problems and an object of the present invention is to provide a method of manufacturing a flash memory cell capable of preventing a phenomenon that a corner of a trench is thinly formed due to a sidewall oxidization process and securing an active region having a desired critical dimension, by forming a tunnel oxide film the trench is formed and etching an exposed portion by a given thickness.

In order to accomplish the above object, a method of manufacturing a flash memory cell according to the present invention, is characterized in that it comprises the steps of sequentially forming a tunnel oxide film, a first polysilicon layer and a pad nitride film on a semiconductor substrate, forming a trench at the semiconductor substrate, forming a trench insulating film by which the trench is buried and then performing a chemical mechanical polishing process to isolate the trench insulating film, removing the pad nitride film and then performing an etch process by which given portions of the trench insulating film are protruded, depositing a second polysilicon layer on the entire structure and then patterning the second polysilicon layer to form a floating gate, and forming a dielectric film and a control gate on the floating gate.

### BRIEF DESCRIPTION OF THE DRAWINGS

The aforementioned aspects and other features of the present invention will be explained in the following description, taken in conjunction with the accompanying drawings, wherein:

FIG. 1A through FIG. 1I are cross-sectional views of flash memory cells for describing a method of manufacturing the flash memory cell according to a preferred embodiment of the present invention.

### DETAILED DESCRIPTION OF PREFERRED EMBODIMENTS

The present invention will be described in detail by way of a preferred embodiment with reference to accompanying drawings, in which like reference numerals are used to identify the same or similar parts.

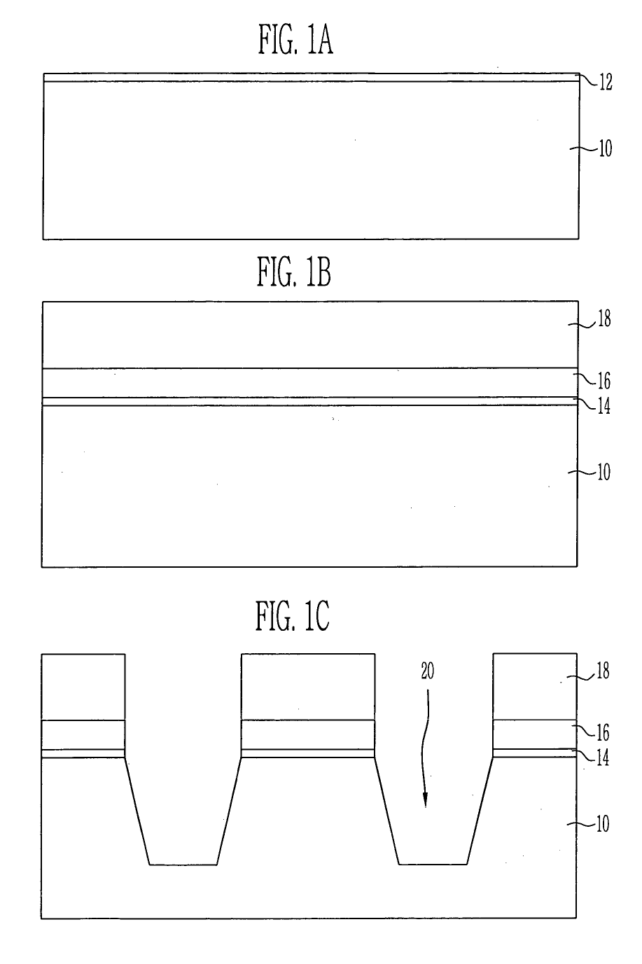

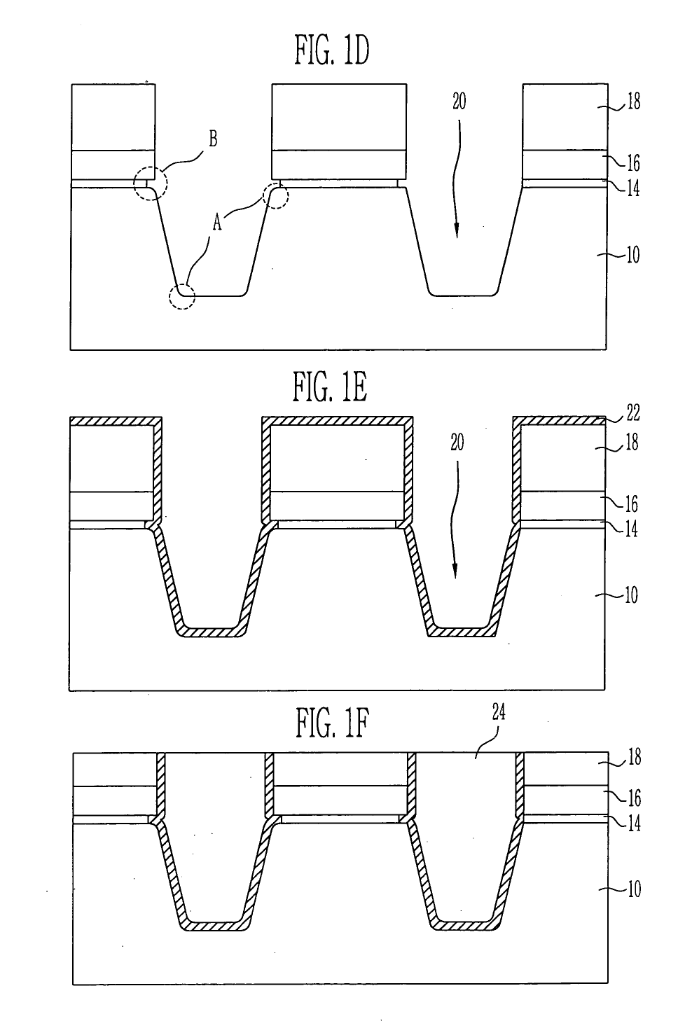

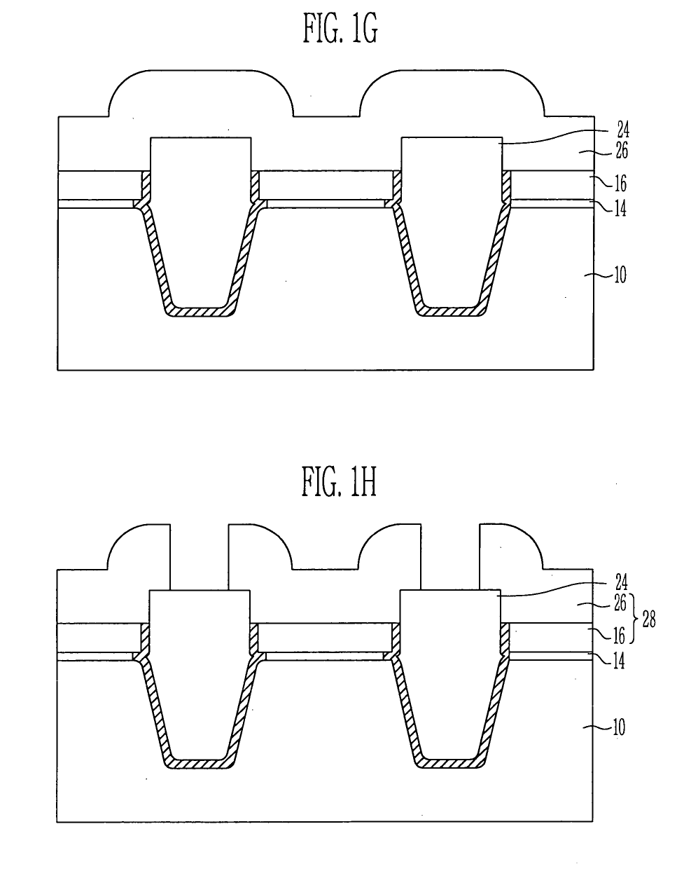

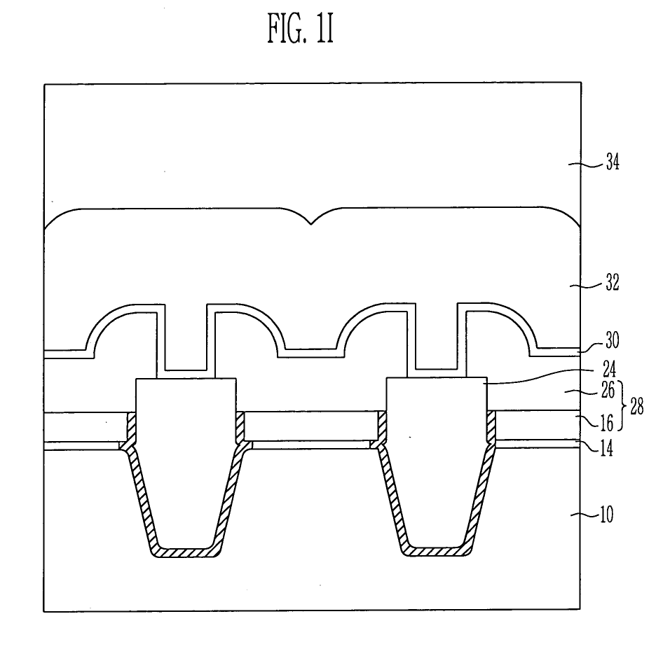

FIG. 1A through FIG. 1I are cross-sectional views of flash memory cells for describing a method of manufacturing the flash memory cell according to a preferred embodiment of the present invention.

Referring now to FIG. 1A, a sacrificial oxide film (SAC) 12 for a pad oxide film is formed on a semiconductor substrate 10. At this time, the sacrificial oxide film 12 is formed in thickness of 70 through 100 Å by means of dry or wet oxidization process at a temperature of 750 through 800° C. in order to process crystal defects on the surface of the semiconductor substrate 10 or the surface of the semiconductor substrate 10.

Also, the semiconductor substrate 10 is cleaned by a pre-treatment cleaning process before the sacrificial oxide film 12 is formed. At this time, the pre-treatment cleaning process includes the processes of dipping the semiconductor substrate 10 into a container where diluted HF (DHF) (HF solution in which H₂O is diluted at the ratio of 50:1) or buffer oxide etchant (BOE) (solution in which HF and NH₄F are mixed at the ratio of 100:1 or 300:1) is filled, cleaning the semiconductor substrate 10 using de-ionized (DI) water, dipping the semiconductor substrate 10 into a container where SC-1 (solution in which NH₄OH/H₂O₂/H₂O solutions are mixed at a given ratio) is filled in order to remove particles remaining on the semiconductor substrate 10, cleaning the semiconductor substrate 10 using DI water and then drying the semiconductor substrate 10.

Next, a well region (not shown) and an impurity region (not shown) are formed at the active region that will be defined by a subsequent STI process, by means of a well ion implantation process and a threshold voltage (VT) ion implantation process using-the sacrificial oxide film 12 as a screen oxide film.

Referring now to FIG. 1B, the entire structure is experienced by a cleaning process in order to remove the sacrificial oxide film 12. A thermal oxidization process is then performed to form a tunnel oxide film 14. At this time, the tunnel oxide film 14 is formed by depositing using a wet oxidization process at a temperature of 750 through 800° C. and then performing an annealing process using N₂ at a temperature of 900 through 910° C. for 20 through 30 minutes in order to minimize an interfacial defect density with the semiconductor substrate 10. Also, the cleaning process for removing the sacrificial oxide film 12 includes the processes of dipping the sacrificial oxide film 12 into a container where DHF or BOE is filled, cleaning the sacrificial oxide film 12 using DI water, dipping the semiconductor substrate 10 into a container where SC-1 is filled in order to remove particles, cleaning the semiconductor substrate 10 using DI water and then drying the semiconductor substrate 10.

Thereafter, a first polysilicon layer 16 that will be used for a buffer or as a part of a floating gate is formed on the entire structure. At this time, the first polysilicon layer 16 is formed by performing a deposition process of a LP-CVD method at a pressure of 0.1 through 3 Torr and temperature of 580 through 620° C. under a SiH₄ or Si₂H₆ and PH₃ gas atmosphere, so that the grain size of the first polysilicon layer 16 is minimized to prevent concentration of an electric field. In addition, the first polysilicon layer 16 is formed in thickness of 250 through 500 Å by injecting phosphorous (P) (for example, in case of a P type) at the doping level of about 1.5E20 through 3.0E20 atoms/cc.

Next, the entire structure is experienced by a deposition process of a LP-CVD method, thus forming a pad nitride film 18 having a thickness of 900 through 2000 Å.

Referring now to FIG. 1C, given portions of the semiconductor substrate 10 including the pad nitride film 18, the first polysilicon layer 16 and the tunnel oxide film 12 are etched by a STI process using the ISO mask, thus forming a trench 20 by which a given portion of the semiconductor substrate 10 is hollowed. At this time, an inner tilt surface of the trench 20 has a tilt angle of 65° through 85°. Also, the pad nitride film 18 has an almost vertical profile. At this time, the semiconductor substrate 10 is divided into an active region and an inactive region (i.e., region in which the trench is formed) by the trench 20.

Referring now to FIG. 1D, an annealing process is performed using a rapid thermal process (RTP) equipment or a fast thermal process (FTP) equipment in order to compensate for etch damage on the inner surface of the trench 20 and make the edge portion ‘A’ rounded. At this time, the annealing process is performed at a temperature of 600 through 1050° C. and low pressure of 250 through 380 Torr for 5 through 10 minutes at the flow rate of hydrogen (H₂) of 100 through 2000 sccm.

Then, the tunnel oxide film 14 is etched by a desired thickness. A cleaning process for minimizing the active region CD (i.e, channel side) is then performed to etch the given portion ‘B’ of the tunnel oxide film 14 that is exposed toward the trench 20. At this time, the cleaning process includes the processes of dipping the sacrificial oxide film 12 into a container where DHF or BOE is filled, cleaning the sacrificial oxide film 12 using DI water, dipping the semiconductor substrate 10 into a container where SC-1 is filled in order to remove particles, cleaning the semiconductor substrate 10 using DI water and then drying the semiconductor substrate 10.

Referring now to FIG. 1E, the entire structure is experienced by a deposition process of a LP-CVD method at a temperature of 650 through 770° C. and low pressure of 0.1 through 1 Torr under Si₃N₄ gas atmosphere, thus forming a liner nitride film 22 of 100 through 500 Å in thickness.

By reference to FIG. 1F, the entire structure is experienced by a deposition process using a high-density plasma (HDP) oxide film so that the trench 20 is buried, thus forming a trench insulating film 24 of 4000 through 10000 Å in thickness. At this time, the deposition process for depositing the trench insulating film 24 is performed using a gap filling process so that void does not occur within the trench 20.

Thereafter, the entire structure is experienced by a chemical mechanical polishing (CMP) process for polishing the pad nitride film 18 by a desired thickness. The trench insulating film 24 is thus isolated with the pad nitride film 18 intervened.

Referring now to FIG. 1G, the entire structure is experienced by a strip process using H₃PO₄ (phosphoric acid) dip out using the first polysilicon layer 16 as an etch barrier layer, so that the pad nitride film is removed. Through the process, the trench insulating film 24 an upper structure of which is protruded is formed. As such, as the upper structure of the semiconductor substrate 10 has a given step (that is, step between the protrusion of the trench insulating film and the first polysilicon layer), an upper portion of the floating gate has a concavo-convex shape due to the step upon a subsequent process.

Next, a wet cleaning process using DHF is performed for the entire structure in order to remove a native oxide film formed on the first polysilicon layer 16. A second polysilicon layer 26 of 400 through 1000 Å in thickness is then formed on the entire structure so that the second polysilicon layer 26 has a concavo-convex shape for maximizing the coupling ratio, by means of a deposition process using the same material to the first polysilicon layer. At this time, the second polysilicon layer 26 is formed within 2 hours after the wet cleaning process is performed.

Referring now to FIG. 1H, an etch process using the floating gate as a mask is performed to etch the second polysilicon layer 26 by which a given portion of the trench insulating film 24 is exposed. With the process, the second polysilicon layer 26 is isolated and a floating gate 28 is thus formed. At this time, the etch process is performed considering the spacing between neighboring floating gates 28.

Thereafter, in order to remove a native oxide film formed on the floating gate 28, a cleaning process including the processes of dipping the sacrificial oxide film 12 into a container where DHF or BOE is filled, cleaning the sacrificial oxide film 12 using DI water, dipping the semiconductor substrate 10 into a container where SC-1 is filled in order to remove particles, cleaning the semiconductor substrate 10 using DI water and then drying the semiconductor substrate 10, is performed.

Referring now to FIG. 1I, a dielectric film 30 having an oxide/nitride/oxide (ONO) structure is formed on the entire structure. At this time, oxide that forms upper and lower portions of the dielectric film 30 is formed in thickness of 35 through 60 Å by using HTO using DCS (SiH₂Cl₂) and N₂O gas having a good partial pressure and a time dependent dielectric breakdown (TDDB) characteristic as a source. More particularly, oxide is formed by means of a LP-CVD method in which oxide is loaded at a temperature of 600 through 700° C. and the temperature is then raised to a temperature of 810 through 850° C. at a low pressure of 0.1 through 3 Torr. Also, nitride that is formed between the upper and lower portions of the dielectric film 30 is formed in thickness of 50 through 65 Å using NH₃ and DCS gas as a reaction gas. More particularly, nitride is formed by means of a LP-CVD method at a temperature of 650 through 800° C. and low pressure of 1 through 3 Torr.

Next, an annealing process is performed in order to improve the quality of the dielectric film 30 and enhance an interface of the layers formed on the semiconductor substrate 10. At this time, the annealing process includes performing a wet oxidization process at a temperature of 750 through 800° C. At this time, the processes of forming and annealing the dielectric film 30 includes forming a thickness conforming to the device characteristic and are performed with almost no time delay in order to prevent contamination of a native oxide film or an impurity between the respective layers.

Thereafter, a third polysilicon layer 32 and a tungsten silicide layer (Wsix) 34 are sequentially formed on the entire structure. At this time, in order to prevent diffusion of fluorine (F) that may cause an increase in the thickness of the oxide film and prevent generation of a WPx layer that is formed by coupling of W and P, the third polysilicon layer 32 is substituted by the dielectric film 30 when the tungsten silicide layer 34 is formed in a subsequent process. More particularly, the third polysilicon layer 32 is formed to have a two-layer structure of a doped layer and an undoped layer by a LP-CVD method in order to prevent prohibit blowing-up of Wsix.

At this time, in order to prohibit formation of a seam and thus reduce a sheet resistance (Rs) of a word line when the subsequent tungsten silicide layer 34 is formed, the ratio in the thickness of the doped layer and the undoped layer is 1:2 or 6:1 and the entire thickness of the doped layer and the undoped layer is 500 though 1000 Å so that spacing of the floating gate 28 can be sufficiently buried. Further, the doped layer and the undoped layer are formed by forming the doped layer using a silicon source gas such as SiH₄ or Si₂H₆ and a PH₃ gas and then consecutively forming the undoped layer without supplying a PH₃ gas into a chamber. Also, the third polysilicon layer 32 is formed at a temperature of 510 through 550° C. and low pressure of 0.1 through 3 Torr.

Meanwhile, the tungsten suicide layer 34 is formed using reaction of MS(SiH₄) or DCS and WF₆ having a low content of fluorine (F), a low annealing stress and a good adhesive strength at a temperature of 300 through 500° C. at a stoichiometry of 2.0 through 2.8 that can minimize Rs (sheet resistance) while implementing an adequate step coverage. Next, an anti-reflection film (not shown) is formed on the entire structure using SiOₓN_{y} or Si₃N₄. The anti-reflection film, the tungsten silicide layer 34, the third polysilicon layer 32 and the dielectric film 30 are sequentially etched using a mask for gate, thus forming a control gate (not shown).

As mentioned above, according to the present invention, a tunnel oxide film is formed before a trench is formed and an exposed portion is then etched by a given thickness. Therefore, the present invention has outstanding advantages that it can prevent a phenomenon that the corner of the trench is thinly formed by a sidewall oxidization process and secure an active region of a desired critical dimension. Further, the present invention can improve electric characteristics such as a retention fail, a high-speed erase of a device, etc. and thus secure reliability of the device.

Further, the present invention has an acting effect that it can reduce the manufacturing cost since a sidewall oxidization process, a threshold voltage screen oxidization process, etc. are avoided.

Also, according to the present invention, the corner of the trench is made rounded by performing an annealing process using hydrogen. Therefore, the present invention can simplify the process.

In addition, a tunnel oxide film is formed, and a liner nitride film is formed in order to protect an exposed portion. Therefore, the present invention has advantages that it can maintain a uniform tunnel oxide film within a channel since damage of the tunnel oxide film by a subsequent process is prevented.

Further, according to the present invention, when a process of depositing a second polysilicon layer forming a floating gate is performed, the size of a concavo-convex portion on the second polysilicon layer is controlled by a deposition target of the second polysilicon layer and the height of the protrusion of a trench insulating film. Therefore, the present invention can effectively increase the coupling ratio by freely controlling an upper surface area of the floating gate.

Therefore, the present invention can form a device of a low cost and high reliability using existing processes and equipments without additional and is complex processes and expensive equipments.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A method of manufacturing a flash memory cell, comprising the steps of:
sequentially forming a tunnel oxide film, a first polysilicon layer and a pad nitride film on a semiconductor substrate;
forming a trench at the semiconductor substrate;
forming a trench insulating film by which the trench is buried and then performing a chemical mechanical polishing (CMP) process to isolate the trench insulating film;
removing the pad nitride film and then performing an etch process by which given portions of the trench insulating film are protruded;
depositing a second polysilicon layer on the entire structure and then patterning the second polysilicon layer to form a floating gate; and
forming a dielectric film and a control gate on the floating gate.

2. The method as claimed in claim 1, further comprising the steps of:
before the tunnel oxide film is formed, forming a sacrificial oxide film on the semiconductor substrate;
performing a well ion implantation process and a threshold voltage ion implantation process for the semiconductor substrate, thus forming a well region and an impurity region; and
removing the sacrificial oxide film.

3. The method as claimed in claim 2, wherein the sacrificial oxide film is formed in thickness of 70 through 100 Å by means of a dry or wet oxidization method at a temperature of 750 through 800° C.

4. The method as claimed in claim 1, wherein the tunnel oxide film is formed by performing a wet oxidization process at a temperature of 750 through 800° C. and then performing an annealing process using N₂ at a temperature of 900 through 910° C. for 20 through 30 minutes.

5. The method as claimed in claim 1, wherein the first polysilicon layer is formed by a low-pressure chemical vapor deposition (LP-CVD) method having a temperature of 580 through 620° C. and low pressure of 0.1 through 3 Torr under a SiH₄ or Si₂H₆ and PH₃ gas atmosphere.

6. The method as claimed in claim 1, further comprising the step of after the trench is formed, performing an annealing process using hydrogen to make the corner of the trench rounded.

7. The method as claimed in claim 6, wherein the annealing process is performed using an RTP or FTP equipment at a temperature of 600 through 1050° C. for 5 through 10 minutes.

8. The method as claimed in claim 6, wherein the flow rate of hydrogen is 100 through 2000 sccm.

9. The method as claimed in claim 1, further comprising the step of after the trench is formed, forming a liner nitride film on the entire structure.

10. The method as claimed in claim 9, wherein the liner nitride film is formed in thickness of 100 through 500 Å by a LP-CVD method at a temperature of 650 through 770° C. and low pressure of 0.1 through 1 Torr.

11. The method as claimed in claim 1, further comprising the step of after the trench is formed, performing a pre-treatment cleaning process in order to etch the tunnel oxide film by a desired thickness.

12. The method as claimed in claim 11, wherein the pre-treatment cleaning process is performed using DHF and SC-1 or BOE and SC-1.

13. The method as claimed in claim 1, wherein the trench insulating film is formed in thickness of 4000 through 10000 Å using a gap filling method.

14. The method as claimed in claim 1, wherein the CMP process is performed to remain the pad nitride film by a given thickness.

15. The method as claimed in claim 1, wherein the etch process is a cleaning process using H₃PO₄ dip out.

16. The method as claimed in claim 1, wherein an upper portion of the second polysilicon layer has a concavo-convex shape by the trench insulating film.

17. The method as claimed in claim 16, wherein the second polysilicon layer is formed in thickness of 400 through 1000 Å.

18. The method as claimed in claim 1, wherein the floating gate includes the first and second polysilicon layers.

19. The method as claimed in claim 1, wherein the dielectric film comprises:
a first oxide film that is formed in thickness of 35 through 60 Å by using HTO using DCS(SiH₂Cl₂) and N₂O gas as a source;
a nitride film that is formed in thickness of 50 through 65 Å on the first oxide film by means of a LP-CVD method using NH₃ and DCS gas as a reaction gas at a temperature of 650 through 800° C. and low pressure of 1 through 3 Torr; and
a second oxide film that is formed in thickness of 35 through 60 Å on the nitride film by using HTO using DCS(SiH₂Cl₂) and N₂O gas as a source.

20. The method as claimed in claim 1, wherein the control gate is formed to have a dual structure of a doped layer and an undoped layer by means of a LP-CVD method.

21. The method as claimed in claim 20, wherein the ratio in the thickness of the doped layer and the undoped layer is 1:2 through 6:1, and the entire thickness of the doped layer and the undoped layer is 500 through 1000 Å.

22. The method as claimed in claim 1, wherein the control gate is formed at a temperature of 510 through 550° C. and low pressure of 0.1 through 3 Torr.

23. The method as claimed in claim 1, further comprising the step of after the control gate is formed, forming a tungsten suicide layer using reaction of MS(SiH₄) or DCS and WF₆ at a temperature of 300 through 500° C. at the stoichiometry of 2.0 through 2.8.
